(19) United States
(12) Patent Application Publication
(10) Pub. No.: US 2008/0049526 A1
(43) Pub. Date: Feb. 28, 2008

(54) SEMICONDUCTOR MEMORY DEVICE WITH DATA AND LOCAL REDUNDANCY MEMORY CELL ARRAYS, AND REDUNDANCY METHOD THEREOF

(75) Inventors: Han-Gyun JUNG, Seoul (KR); Seung-Bum KO, Gyeonggi-do (KR); Nak-Won HEO, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/829,854

(22) Filed: Jul. 27, 2007

(30) Foreign Application Priority Data
Jul. 28, 2006 (KR) 10-2006-0071568

(51) Int. Cl. G11C 29/24

(52) U.S. Cl. 365/200; 365/225.7

(57) ABSTRACT

A semiconductor memory device includes both a data redundancy memory cell array and a local redundancy memory cell array. Cells of the data redundancy memory cell array and/or cells the local redundancy memory cell arrays may be substituted for one or more defective cells of a normal memory cell array, depending on the number of defects generated in the normal memory cell array. An embodiment of a semiconductor memory device may include a plurality of normal memory blocks, each normal memory block comprising a normal memory cell array and a local redundancy memory cell array, at least one data line redundancy memory block, each data line redundancy memory block comprising a data redundancy memory cell array, and a redundancy controller to substitute columns of the data line redundancy memory cell array for some columns of at least two columns in each normal memory cell array, and to substitute columns of the local redundancy memory cell array for the remaining columns of the at least two columns.

### CROSS-REFERENCE TO RELATED PATENT APPLICATION

This application claims the benefit of Korean Patent Application No. 10-2006-0071568, filed on Jul. 28, 2006, in the Korean Intellectual Property Office, the disclosure of which is incorporated herein in its entirety by reference.

### BACKGROUND

1. Field of the Invention

The present invention relates to a semiconductor memory device and a redundancy method thereof, and more particularly, to a semiconductor memory device including both a data line redundancy memory cell array and a local redundancy memory cell array, and a redundancy method of the semiconductor memory device.

2. Description of the Related Art

To enhance the yield of semiconductor memory devices, predetermined redundancy cells are substituted for defective cells for a when a defect is generated in a memory cell array. The predetermined redundancy cells are included in a predetermined redundancy memory cell array. Using this method, the defective cells are essentially replaced by the predetermined redundancy cells, generally in units of columns of memory cells.

However, if defects are generated in multiple columns of a memory cell array, it is difficult to substitute columns of the redundancy memory cell array for all of the defective columns of the memory cell array. That is, there is little flexibility in manner in which the predetermined redundancy cells can be substituted for defective cells when defects are generated in multiple columns of a memory cell array.

### SUMMARY

The present invention provides a semiconductor memory device which can perform a redundancy operation using both a data redundancy memory cell array and a local redundancy memory cell array. The present invention also provides a redundancy method which is performed by a semiconductor memory device using both a data redundancy memory cell array and a local redundancy memory cell array.

According to one aspect of the present invention, there is provided a semiconductor memory device comprising: a plurality of normal memory blocks, each normal memory block comprising a normal memory cell array and a local redundancy memory cell array, wherein at least one column in the local redundancy memory cell array may be substituted for at least one defective column in the normal memory cell array; at least one data line redundancy memory block, each data line redundancy memory block comprising a data redundancy memory cell array in which at least one column of the data line redundancy memory cell array may be substituted for at least one defective column in a normal memory cell array of each normal memory block; and a redundancy controller to substitute columns of the data line redundancy memory cell array for some columns of at least two columns in each normal memory cell array, and to substitute columns of the local redundancy memory cell array for the remaining columns of the at least two columns, when defects are generated in the at least two columns.

According to another aspect of the present invention, there is provided a semiconductor memory device comprising: a plurality of normal memory blocks; and at least one data line redundancy memory block; wherein if at least one address bit of a first column in each normal memory cell array is equal to at least one address bit of a second column in the normal memory cell array, and defects are generated in at least two columns of columns which are simultaneously activated, a column of the data line redundancy memory cell array is substituted for one of the at least two columns, and a column of the local redundancy memory cell array is substituted for the other of the at least two columns.

According to vet another aspect of the present invention, there is provided a semiconductor memory device comprising logic to substitute cells of a data line redundancy memory cell array and/or cells of one or more of a local redundancy memory cell arrays for one or more defective cells of normal memory cell arrays, depending on the number of defects generated in the normal memory cell arrays.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a semiconductor memory device including both a data redundancy memory cell array and a local redundancy memory cell array, according to an embodiment of the present invention; and

FIG. 2 is a block diagram of an embodiment of the redundancy controller illustrated in FIG. 1.

### DETAILED DESCRIPTION

The attached drawings for illustrating preferred embodiments of the present invention are referred to in order to gain a sufficient understanding of the present invention, the merits thereof, and the objectives accomplished by the implementation of the present invention. Hereinafter, the present invention will be described in detail by explaining preferred embodiments of the invention with reference to the attached drawings. Like reference numerals in the drawings denote like elements.

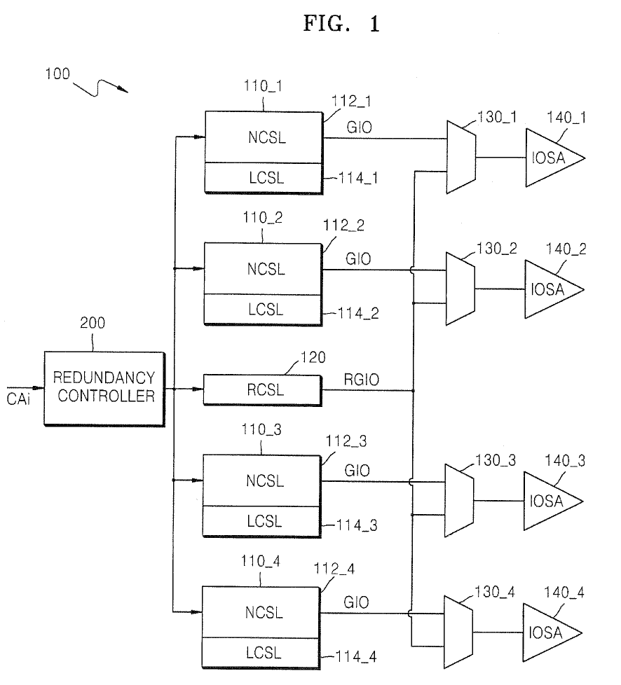

FIG. 1 is a block diagram of a semiconductor memory device 100 including both a data redundancy memory cell array and a local redundancy memory cell array, according to an embodiment of the present invention.

Referring to FIG. 1, the semiconductor memory device 100 includes a plurality of normal memory blocks 110_1 through 110_4, at least one data line redundancy memory block (not shown), and a redundancy controller 200.

The plurality of normal memory blocks 110_1 through 110_4 include a plurality of normal memory cell arrays 112_1 through 112_4, and a plurality of local redundancy memory cell arrays 114_1 through 114_4 in which defective columns in the normal memory cell arrays 112_1 through 112_4 are replaced by redundancy cells in units of a columns (i.e., redundancy columns are substituted for the defective columns). The data line redundancy memory block includes a data redundancy memory cell array 120 having redundancy columns which are substituted for defective columns in the normal memory cell arrays 112_1 through 112_4 of the plurality of normal memory blocks 110_1 through 110_4.

When defects are generated in at least two columns in a normal memory cell array (for example, the normal memory cell array 112_1), the redundancy controller 200 substitutes columns of the data line redundancy memory cell array 120 for some columns of the at least two columns, and substitutes columns of the local redundancy memory cell array 114_1 for the remaining columns of the at least two columns.

In some embodiments, defects may be generated in at least two columns when at least one address bit of one column is equal to at least one address bit of another column. In other embodiments, may be generated in at least two columns when the column address of one of the at least two columns is equal to the column address of another of the at least two columns, excluding the least significant bit (LSB). For example, if it is assumed that a column address of a column of a normal memory cell array (for example, the normal memory cell array 112_1) consists of 12 bits CA0 through CA11, the bits CA0 through CA10 of one column are equal to CA0 through CA10 of another column.

When at least two defective columns are simultaneously activated and data of memory cells belonging to the columns is simultaneously read, the redundancy controller 200 substitutes columns of the data line redundancy memory cell array for some columns of the defective columns, and substitutes columns of the local redundancy memory cell array for the remaining columns of the defective columns.

For example, assuming that a column address of a column of a normal memory cell array (for example, the normal memory cell array 112_1) consists of 12 bits CA0 through CA11, it is assumed that the 11 bits CA0 through CA10 of a column address of one column are equal to the corresponding bits of a column address of another column, and the two columns from which data will be read are simultaneously activated, so that defects are generated in the two columns. In this case, a column of the data line redundancy memory cell array is substituted for one of the two columns, and a column of the local redundancy memory cell array is substituted for the other of the two columns. Also, if a defect is generated in a single column of a normal memory cell array, a column of the data line redundancy memory cell array is substituted for that column.

That is, semiconductor memory device according to the present invention may perform a redundancy operation using only the data line redundancy memory cell array, or using both the data line redundancy memory cell array and the local redundancy memory cell array, according to the number of columns in which defects are generated in a normal memory cell array. Thus, when defects are generated in a plurality of columns in a normal memory block, all of the plurality of columns in which the defects are generated can be replaced by different columns.

The local redundancy memory cell array 114_1 can be included in the normal memory block 110_1 to which the normal redundancy memory cell array 112_1 belongs.

Again returning to FIG. 1, the semiconductor memory device 100 can further include a plurality of multiplexers 130_1 through 130_4 corresponding to the normal memory cell blocks 112_1 through 112_4. Each multiplexer selects either the data output from the corresponding normal memory cell block, or the data output from the data line redundancy memory cell array 120, and outputs the selected data to the corresponding one of the input/output sense amplifiers 140_1 through 140_4.

If a column of the data line redundancy memory cell array 120 is substituted for a column of the normal memory cell array e.g., 112_1, the multiplexer e.g., 130_1 outputs data from the data line redundancy memory cell array 120 to the input/output sense amplifier 140_1. If a column of the local redundancy memory cell array e.g., 114_1, is substituted for a column of the normal memory cell array e.g., 112_1, the multiplexer 130_1 outputs data from the local redundancy memory cell array e.g., 114_1, to the input/output sense amplifier 140_1.

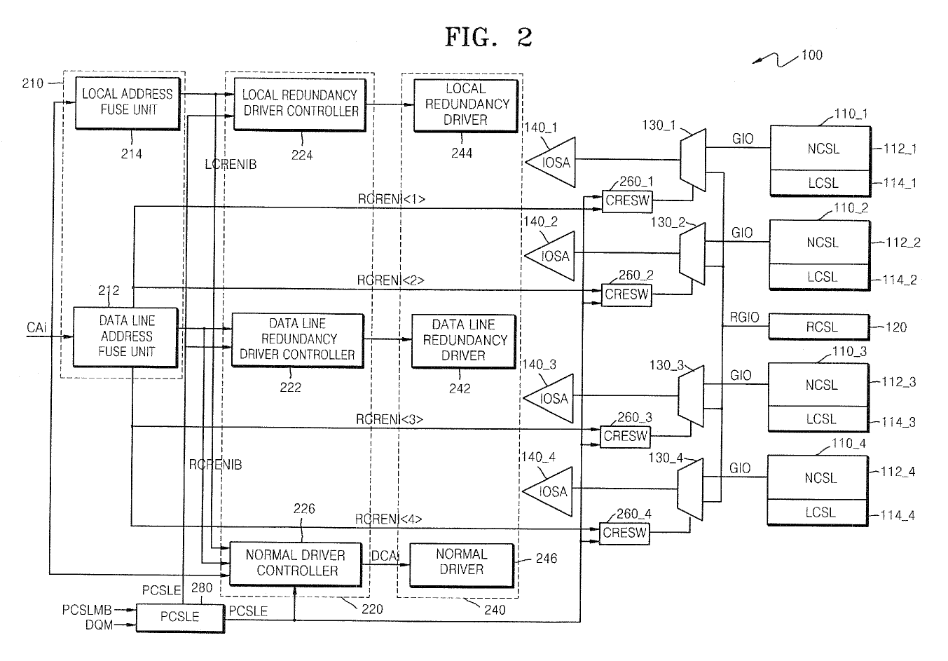

FIG. 2 is a detailed block diagram of an embodiment of the redundancy controller 200 illustrated in FIG. 1. Referring to FIG. 2, the redundancy controller 200 includes a fuse unit 210 and redundancy driver units 220, 240. The fuse unit 210 cuts off fuses corresponding to column addresses of columns in which defects are generated. The redundancy driver units 220, 240 receives a column address CAi of a column of a normal memory cell array (for example, 112_1), from which data will be read, and then activates a column of the data line redundancy memory cell array 120 or the local redundancy memory cell array (for example, 114_1) if the column address CAi corresponds to a fuse which has been cut off. If the column address CAi corresponds to a fuse which has been not cut off, the redundancy driver units 220 and 240 activate the column of the normal memory cell array 112_1.

The fuse unit 210 can include a local address fuse unit 214 and a data line address fuse unit 212. Each of the local address fuse unit 214 and the data line address fuse unit 212 includes fuses corresponding to column addresses of the normal memory cell arrays 112_1 through 112_4, and outputs information (hereinafter, referred to as “fuse cut-off information”) indicating whether or not a fuse corresponding to a received column address CAi has been cut off. When defects are generated in at least two columns of a normal memory cell array (for example, 112_1), the data line address fuse unit 212 cuts off fuses corresponding to column addresses of some columns of the at least two columns in which the defects are generated, and the local address fuse unit 214 cuts off fuses corresponding to column addresses of the remaining columns of the at least two columns.

The redundancy driver units 220, 240 can include a data line redundancy driver 242 and a local redundancy driver 244. The data line redundancy driver 242 activates the corresponding columns in the data line redundancy memory cell array 120 according to the fuse cut-off information received from the data line address fuse unit 212. The local redundancy driver 244 activates the corresponding columns in a local redundancy memory cell array (for example, 114_1), according to the fuse cut-off information received from the local address fuse unit 214.

The redundancy driver units 220, 240 can further include a data line redundancy driver controller 222 and a local redundancy driver controller 224. The data line redundancy driver controller 222 operates the data line redundancy driver 242 when the fuse of the data line address fuse unit 212 corresponding to the received column address CAi is cut off. The local redundancy driver controller 224 operates the local redundancy driver 244 when the fuse of the local address fuse unit 214 corresponding to the received column address CAi is cut off.

The redundancy controller 200 can further include a redundancy enable unit 280. The redundancy enable unit 280 enables the data line redundancy driver controller 222 and the local redundancy driver controller 224 in response to a redundancy enable signal PCSLMB and a data masking signal DQM. The redundancy enable signal PCSLMB indicates whether the semiconductor memory device 100 has to perform a redundancy operation. The data masking signal DQM indicates whether data is input to the semiconductor memory device 100.

Hereinafter, the operation of the semiconductor memory device 100 will be described in detail with reference to FIG. 2. The redundancy enable unit 280 outputs a redundancy signal PCSLE in response to a redundancy enable signal PCSLMB whose logic level indicates that the semiconductor memory device 100 has to perform a redundancy operation, and a data masking signal DQM whose logic level indicates that data is input to the semiconductor memory device 100.

Hereinafter, it is assumed that at least one address bit of some columns of a normal memory cell array (for example, 112_1) are equal to at least one address bit of other columns of the normal memory cell array 112_1, and the columns which have at least one equal bit are simultaneously activated. Also, it is assumed that defects are generated in at least two columns which have at least one equal bit are simultaneously activated. In this case, the data line address fuse unit 212 cuts off fuses corresponding to column addresses of some columns of the at least two columns in which the defects are generated, and the local address fuse unit 214 cuts off fuses corresponding to column addresses of the remaining columns of the at least two columns. When the data line redundancy driver controller 222 receives a redundancy signal PCSLE and a column address CAi, the data line redundancy driver controller 222 operates the data line redundancy driver 242 if a fuse of the data line address fuse unit 212 corresponding to the column address CAi is cut off. The local redundancy driver controller 244 also receives the redundancy signal PCSLE and the column address CAi, and operates the local redundancy driver 244 if a fuse of the local address fuse unit 214 corresponding to the column address CAi is cut off. Then, the data line redundancy driver 242 activates the corresponding column of the data line redundancy memory cell array 120. The local redundancy driver 244 activates the corresponding column of a local redundancy memory cell array (for example, 114_1).

Also, it is assumed that a defect is generated in one column among the plurality of columns which are simultaneously activated and have at least one equal bit of address bits. In this case, the data line address fuse unit 212 cuts off a fuse corresponding to the column address of the one column in which the defect is generated, and the local address fuse unit 214 cuts off no fuse. Accordingly, the data line redundancy driver controller 222 operates the data line redundancy driver 242, and the local redundancy driver controller 224 does not operate the local redundancy driver 244. The normal driver controller 226 operates the normal driver 246 in response to a received column address CAi. As a result, the data line redundancy driver 242 activates the corresponding column of the data line redundancy memory cell array 120, and the local redundancy driver 244 activates no column. Also, the normal driver 246 activates a column corresponding to the column address CAi.

It is further assumed that at least one address bit of a column of a normal memory cell array (for example, 112_1) is equal to at least one address bit of address bits of a different column, and no defect is generated in columns which are simultaneously activated. In this case, both the data line address fuse unit 212 and the local address fuse unit 214 cut off no fuse. Accordingly, the data line redundancy driver controller 222 and the local redundancy driver controller 224 do not operate the data line redundancy driver 242 and the local redundancy driver 244. However, the normal driver controller 226 operates the normal driver 246 in response to a received column address CAi. As a result, the data line redundancy driver 242 and the local redundancy driver 244 activate no column, and the normal driver 246 activates a column corresponding to the column address CAi.

Hereinafter, a redundancy method which is performed by the semiconductor memory device 100 according to the present invention is described. The redundancy method comprises cutting off a fuse corresponding to a received column address; receiving a column address of a column from which data will be read; and substituting a column in which a defect is generated for a different column.

The cutting off of the fuse corresponding to the received column address includes cutting off a fuse corresponding to the received column address among fuses of the local address fuse unit and the data line address fuse unit, if at least one bit of the column address is equal to at least one bit of a different column address, and defects are generated in two columns which are simultaneously activated. The substituting of the different column for the column in which the defect is generated includes substituting a column of the data line memory cell array for the column in which the defect is generated, if a fuse of the data line address fuse unit corresponding to the received column address is cut off, and substituting a column of the local memory cell array for the column in which the defect is generated, if a fuse of the local address fuse unit corresponding to the received column address is cut off.

The redundancy method is based on some of the same technical concepts as the semiconductor memory device 100 as described above, and utilizes some of the same construction of the semiconductor memory device 100. Accordingly, the redundancy method can be easily understood by one of ordinary skill in the art from the above description.

As described above, in a semiconductor memory device and method according to the present invention, when defects are generated in a plurality of columns of a memory cell array, it is possible to substitute redundancy columns for all the columns in which the defects are generated.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor memory device comprising:
a plurality of normal memory blocks, each normal memory block comprising a normal memory cell array and a local redundancy memory cell array, wherein at least one column in the local redundancy memory cell array may be substituted for at least one defective column in the normal memory cell array;
at least one data line redundancy memory block, each data line redundancy memory block comprising a data redundancy memory cell array in which at least one column of the data line redundancy memory cell array may be substituted for at least one defective column in a normal memory cell array of each normal memory block; and
a redundancy controller to substitute columns of the data line redundancy memory cell array for some columns of at least two columns in each normal memory cell array, and to substitute columns of the local redundancy memory cell array for the remaining columns of the at least two columns, when defects are generated in the at least two columns.

2. The semiconductor memory device of claim 1, wherein defects are generated in the at least two columns when at least one column address bit of one of the at least two columns is equal to at least one column address bit of another of the at least two columns.

3. The semiconductor memory device of claim 1, wherein defects are generated in the at least two columns when the column address of one of the at least two columns is equal to the column address of another of the at least two columns, excluding the least significant bit (LSB).

4. The semiconductor memory device of claim 1, wherein, when the at least two columns in which the defects are generated are simultaneously activated, and data of memory cells belonging to the at least two columns is simultaneously read, the redundancy controller substitutes columns of the data line redundancy memory cell array for the some columns of the at least two columns, and substitutes columns of the local redundancy memory cell array for the remaining columns of the at least two columns.

5. The semiconductor memory device of claim 1, wherein the local redundancy memory cell array in which the at least one defective column is substituted for the at least one different column is included in the normal memory block to which the normal redundancy memory cell array having the at least one defective column belongs.

6. The semiconductor memory device of claim 1, wherein the redundancy controller comprises:
a fuse unit to cut off a fuse corresponding to a column address of a column having a defect in one of the normal memory cell arrays; and
a redundancy driver to receive a column address of a column of one of the normal memory cell arrays from which data will be read, to activate a column of the data line redundancy memory cell array or the local redundancy memory cell array if the column address corresponds to the fuse which is cut off, and to activate the column of the normal memory cell array when the column address corresponds to a fuse which is not cut off.

7. The semiconductor memory device of claim 6, wherein:
the fuse unit comprises a local address fuse unit and a data line address fuse unit, each of the local address fuse unit and the data line address fuse unit comprising a plurality of fuses corresponding to column addresses of normal memory cell arrays, each fuse unit to output fuse cut-off information indicating whether the fuse corresponding to the received column address is cut off; and
when defects are generated in at least two columns one of the normal memory cell arrays, the data line address fuse unit cuts off fuses corresponding to column addresses of some columns of the at least two columns, and the local address fuse unit cuts off fuses corresponding to column addresses of the remaining columns of the at least two columns.

8. The semiconductor memory device of claim 7, wherein the redundancy driver unit comprises:
a data line redundancy driver to activate a column corresponding to the received column address in the data line redundancy memory cell array according to the fuse cut-off information received from the data line address fuse unit; and
a local redundancy driver to activate a column corresponding to the received column address in the local redundancy memory cell array according to the fuse cut-off information received from the local address fuse unit.

9. The semiconductor memory device of claim 8, wherein the redundancy driver further comprises:
a data line redundancy driver controller to operate the data line redundancy driver if a fuse of the data line address fuse unit corresponding to the received column address is cut off: and
a local redundancy driver controller to operate the local redundancy driver if a fuse of the local address fuse unit corresponding to the received column address is cut off.

10. The semiconductor memory device of claim 9, further comprising a redundancy enable unit to enable the data line redundancy driver controller and the local redundancy driver controller in response to a redundancy enable signal and a data masking signal.

11. The semiconductor memory device of claim 1, further comprising a plurality of multiplexers corresponding to the plurality of normal memory blocks, respectively, to selectively output data from either a corresponding normal memory cell block or from a data line redundancy memory cell array.

12. The semiconductor memory device of claim 11, wherein each multiplexer outputs data received from the corresponding data line redundancy memory cell array if a column of the normal memory cell array is substituted for a column of the data line redundancy memory cell array, and outputs data received from the corresponding local redundancy memory cell array if the column of the normal memory cell array is substituted for a column of the local redundancy memory cell array.

13. A semiconductor memory device comprising:
a plurality of normal memory blocks, each normal memory block comprising a normal memory cell array and a local redundancy memory cell array, wherein at least one column in the local redundancy memory cell array may be substituted for at least one defective column in the normal memory cell array; and
at least one data line redundancy memory block, each data line redundancy memory block comprising a data redundancy memory cell array in which at least one column of the data line redundancy memory cell array may be substituted for at least one defective column in a normal memory cell array of each normal memory block;
wherein, if at least one address bit of a first column in each normal memory cell array is equal to at least one address bit of a second column in the normal memory cell array, and defects are generated in at least two columns of columns which are simultaneously activated, a column of the data line redundancy memory cell array is substituted for one of the at least two columns, and a column of the local redundancy memory cell array is substituted for the other of the at least two columns.

14. The semiconductor memory device of claim 13, wherein, if the at least one address bit of the column in the normal memory cell array is equal to the at least one address bit of the different column in the normal memory cell array, and a defect is generated in one of the at least two columns which are simultaneously activated, a column of the data line redundancy memory cell array is substituted for the column in which the defect is generated.

15. The semiconductor memory device of claim 13, wherein the column of the data line redundancy memory cell array is substituted for one of the at least two columns, and the column of the local redundancy memory cell array is substituted for the other of the at least two columns when the column address of the first column is equal to the column address of the second column, excluding the least significant bit (LSB).

16. A redundancy method for a semiconductor device, the semiconductor device comprising: a plurality of normal memory blocks, each normal memory block comprising a normal memory cell array and a local redundancy memory cell array in which at least one column of the local redundancy memory cell array may be substituted for at least one defective column of the normal memory cell array; and at least one data line redundancy memory block, each data line redundancy memory block comprising a data redundancy memory cell array in which at least one column of the data line redundancy memory cell array may be substituted for at least one defective column in a normal memory cell array of each normal memory block; and a local address fuse unit and a data line address fuse unit, each of the local address fuse unit and the data line address fuse unit comprising a plurality of fuses corresponding to a plurality of column addresses of the normal memory cell arrays, the redundancy method comprising:
if at least one address bit of a column in each normal memory cell array is equal to at least one address bit of a different column of the normal memory cell array, and defects are generated in two columns of columns which are simultaneously activated, cutting off a fuse corresponding to a received column address among fuses of the local address fuse unit and the data line address fuse unit;
if the at least one address bit of the column in the normal memory cell array is equal to the at least one address bit of the different column of the normal memory cell array, and a defect is generated in one of the columns which are simultaneously activated, cutting off the fuse corresponding to the received column address among the fuses of the data line address fuse unit;
receiving a column address of a column from which data will be read; and
if a fuse of the data line address fuse unit corresponding to the received column address is cut off, substituting of the data line memory cell array for the column in which the defect is generated, and if a fuse of the local address fuse unit corresponding to the received column address is cut off, substituting a column of the local memory cell array for the column in which the defect is generated.

17. A semiconductor memory device comprising:
a plurality of normal memory blocks, each normal memory block comprising a normal memory cell array and a local redundancy memory cell array;
at least one data line redundancy memory cell array in which at least one column of the data line redundancy memory cell array; and
logic to substitute cells of the data line redundancy memory cell array and/or cells of one or more of the local redundancy memory cell arrays for one or more defective cells of the normal memory cell arrays, depending on the number of defects generated in the normal memory cell arrays.

18. The semiconductor memory device of claim 17, wherein the logic may substitute only cells of the data line redundancy memory cell array, or a combination of cells of the data line redundancy memory cell array and cells of one or more of the local redundancy memory cell arrays, depending on the number of defects generated in the normal memory cell arrays.

19. The semiconductor memory device of claim 17, wherein the logic may substitute only cells of the local redundancy memory cell array, or a combination of cells of the data line redundancy memory cell array and cells of one or more of the local redundancy memory cell arrays, depending on the number of defects generated in the normal memory cell arrays.

20. The semiconductor memory device of claim 18, wherein the logic may substitute a column of the data line redundancy memory cell array for a first defective column of one of the normal memory cell arrays, and may substitute a column of the local redundancy memory cell array for a second defective column of the one of the normal memory cell arrays.
